(19) United States
(12) Patent Application Publication
(10) Pub. No.: US 2026/0244801 A1
(43) Pub. Date: Aug. 20, 2026

(54) SPACE OUTLINE CALCULATION DEVICE AND METHOD

(71) Applicant: HTC Corporation, Taoyuan City (TW)

(72) Inventor: Hung Chi HUANG, Taoyuan City (TW)

(21) Appl. No.: 19/055,476

(22) Filed: Feb. 17, 2025

(51) Int. Cl. G06F 30/13

(52) U.S. Cl. CPC G06F 30/13

(57) ABSTRACT

A space outline calculation device and method are provided. The device projects three-dimensional map points onto a projection plane to generate projection points projected on the projection plane. The device calculates an indoor plane outline based on the projection points. The device generates fitting planes with a normal vector parallel to a gravity vector based on the three-dimensional map points. The device determines a floor fitting plane and a ceiling fitting plane among the fitting planes. The device generates a space outline corresponding to a physical indoor space based on the indoor plane outline, the floor fitting plane, and the ceiling fitting plane.

### BACKGROUND

### Field of Invention

The present invention relates to a space outline calculation device and method. More particularly, the present invention relates to a space outline calculation device and method that can correctly calculate the space outline corresponding to a physical indoor space.

### Description of Related Art

In the prior art, electronic devices can execute various technologies and applications by generating a plurality of three-dimensional map points corresponding to a physical indoor space through simultaneous localization and mapping (SLAM) operations.

However, among these three-dimensional map points, there may be many map points that do not actually exist in the map space, resulting in uncertainty in data calculation. For example, when building an indoor space map, since the floor in the space has a reflective material (such as a marble floor), the light reflections produced by the reflections create virtual images (e.g., the map points are imaged below the floor or the map points are located outside the map space).

In addition, since these map points may disappear in certain situations (e.g., when the lights are turned off). Therefore, this problem further increases the uncertainty of data calculation during map calculation.

Accordingly, if the space outline can be calculated correctly, the three-dimensional map points can be corrected through the space outline (e.g., reduce the calculation weight of the map points outside the space outline) to improve the accuracy of the three-dimensional map points.

Accordingly, there is an urgent need for a space outline calculation technology that can accurately calculate the space outline corresponding to the physical indoor space.

### SUMMARY

An objective of the present disclosure is to provide a space outline calculation device. The space outline calculation device comprises a storage and a processor. The processor is electrically connected to the storage. The storage is configured to store a plurality of three-dimensional map points corresponding to a physical indoor space. The processor projects the plurality of three-dimensional map points onto a projection plane to generate a plurality of projection points projected on the projection plane, wherein a first normal vector of the projection plane is parallel to a gravity vector measured by the space outline calculation device. The processor calculates an indoor plane outline based on the plurality of projection points. The processor generates a plurality of fitting planes with a second normal vector parallel to a gravity vector based on the plurality of three-dimensional map points. The processor determines a floor fitting plane and a ceiling fitting plane among the plurality of fitting planes. The processor generates a space outline corresponding to the physical indoor space based on the indoor plane outline, the floor fitting plane, and the ceiling fitting plane.

Another objective of the present disclosure is to provide a space outline calculation method, which is adapted for use in an electronic device. The electronic device is configured to store a plurality of three-dimensional map points corresponding to a physical indoor space. The space outline calculation method comprises the following steps: projecting the plurality of three-dimensional map points onto a projection plane to generate a plurality of projection points projected on the projection plane, wherein a first normal vector of the projection plane is parallel to a gravity vector measured by the electronic device; calculating an indoor plane outline based on the plurality of projection points; generating a plurality of fitting planes with a second normal vector parallel to a gravity vector based on the plurality of three-dimensional map points; determining a floor fitting plane and a ceiling fitting plane among the plurality of fitting planes; and generating a space outline corresponding to the physical indoor space based on the indoor plane outline, the floor fitting plane, and the ceiling fitting plane.

According to the above descriptions, the space outline calculation technology (at least including the device and the method) provided by the present disclosure generates an indoor plane outline through the operation of projecting a plurality of three-dimensional map points and the fitting operation. Next, the space outline calculation technology provided by the present disclosure generates a plurality of fitting planes based on the three-dimensional map points, and determines a floor fitting plane and a ceiling fitting plane from the fitting planes. Finally, the space outline calculation technology provided by the present disclosure combines the indoor plane outline, the floor fitting plane, and the ceiling fitting plane to generate a space outline corresponding to the physical indoor space. The space outline calculation technology provided by the present disclosure can accurately calculate the space outline of the physical indoor space, and correct the three-dimensional map points through the space outline to improve the accuracy of the three-dimensional map points.

The detailed technology and preferred embodiments implemented for the subject disclosure are described in the following paragraphs accompanying the appended drawings for people skilled in this field to well appreciate the features of the claimed invention.

### BRIEF DESCRIPTION OF THE DRAWINGS

FIG. 1 is a schematic diagram depicting the structure of the space outline calculation device of the first embodiment;

FIG. 2 is a schematic diagram depicting the structure of the space outline calculation device of some embodiments;

FIG. 3A is a schematic diagram depicting the projection operation of some embodiments;

FIG. 3B is a schematic diagram depicting the projection operation of some embodiments;

FIG. 4A is a schematic diagram depicting the fitting lines of some embodiments;

FIG. 4B is a schematic diagram depicting the fitting lines of some embodiments;

FIG. 5A is a schematic diagram depicting the fitting line segments of some embodiments;

FIG. 5B is a schematic diagram depicting the fitting line segments and the intersection points of some embodiments;

FIG. 6A is a schematic diagram depicting the fitting planes of some embodiments;

FIG. 6B is a schematic diagram depicting the floor fitting plane and the ceiling fitting plane of some embodiments;

FIG. 7A is a schematic diagram depicting the vertical planes of some embodiments;

FIG. 7B is a schematic diagram depicting the vertical planes of some embodiments;

FIG. 8 is a schematic diagram depicting the space outline of some embodiments;

FIG. 9A is a schematic diagram depicting the operations of some embodiments;

FIG. 9B is a schematic diagram depicting the operations of some embodiments; and

FIG. 10 is a partial flowchart depicting the space outline calculation method of the second embodiment.

### DETAILED DESCRIPTION

In the following description, a space outline calculation device and method according to the present disclosure will be explained with reference to embodiments thereof. However, these embodiments are not intended to limit the present disclosure to any environment, applications, or implementations described in these embodiments. Therefore, description of these embodiments is only for purpose of illustration rather than to limit the present disclosure. It shall be appreciated that, in the following embodiments and the attached drawings, elements unrelated to the present disclosure are omitted from depiction. In addition, dimensions of individual elements and dimensional relationships among individual elements in the attached drawings are provided only for illustration but not to limit the scope of the present disclosure.

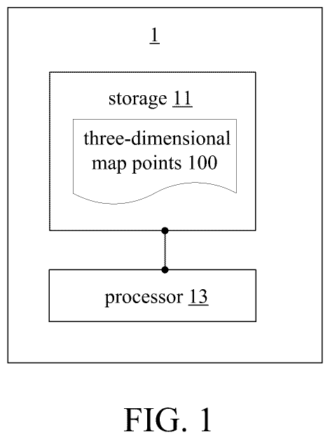

The first embodiment of the present disclosure is a space outline calculation device 1, and a schematic diagram of which is depicted in FIG. 1. The space outline calculation device 1 comprises an storage 11 and a processor 13. The processor 13 is electrically connected to the storage 11. In the present embodiment, the storage 11 is configured to store a plurality of three-dimensional map points 100 corresponding to a physical indoor space (e.g., a room). Each of the three-dimensional map points may at least include a three-dimensional coordinate value corresponding to the physical space.

It shall be appreciated that the storage 11 may be a memory, a Universal Serial Bus (USB) disk, a hard disk, a Compact Disk (CD), a mobile disk, or any other storage medium or circuit known to those of ordinary skill in the art and having the same functionality. The processor 13 may be any of various processors, Central Processing Units (CPUs), microprocessors, digital signal processors or other computing apparatuses known to those of ordinary skill in the art.

The purpose of the operation of the present disclosure is briefly described first. The space outline calculation device 1 can correctly calculate the actual space outline corresponding to the physical space through the operation disclosed in the present disclosure to exclude irregular three-dimensional map points. Accordingly, when subsequent applications need to use three-dimensional map point information, the computing device may not use three-dimensional map points outside the spatial outline or reduce the map calculation weight, thereby improving the correctness of the three-dimensional map points and the accuracy of subsequent calculation operations. The following will describe the details of the operation of the present disclosure.

First, in the present embodiment, the processor 13 first projects the three-dimensional map points in the space onto the same plane through projection to perform fitting calculations to estimate possible spatial boundaries (e.g., the walls of a room).

Specifically, the processor 13 projects the plurality of three-dimensional map points onto a projection plane to generate a plurality of projection points projected on the projection plane, wherein a normal vector (i.e., the first normal vector referred to in some paragraphs of the present disclosure) of the projection plane is parallel to a gravity vector measured by the space outline calculation device. Next, the processor 13 calculates an indoor plane outline based on the plurality of projection points.

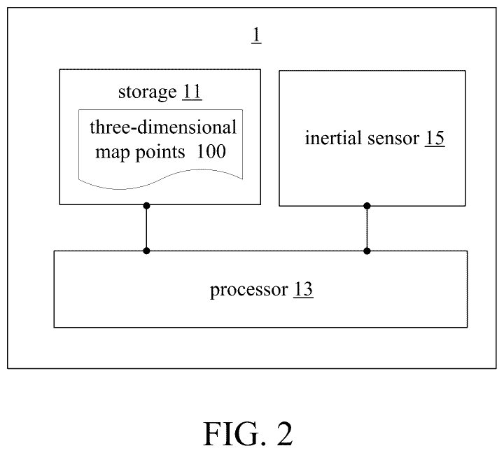

In some embodiments, as shown in FIG. 2, the space outline calculation device may further comprise an inertial sensor 15. The inertial sensor 15 is electrically connected to the processor 13, and the inertial sensor 15 is configured to sense the gravity vector. For example, the inertial sensor 15 may be an inertial measurement unit (IMU). It shall be appreciated that in the present disclosure, the inertial sensor IMU may only include a gyroscope and an accelerometer, without configurations such as a magnetometer or a barometer.

In some embodiments, the processor 13 may evaluate a plurality of groups of data points (i.e., projection points) located on the projection plane, and calculate the distances between the data points and the fitting model to find a plurality of most suitable fitting lines. Specifically, the processor 13 performs a fitting operation on the projection points to calculate a plurality of fitting lines located on the projection plane. Next, the processor 13 generates the indoor plane outline based on the fitting lines.

For example, the space outline calculation device 1 may use a random sampling consensus (RANSAC) algorithm to identify the best model among the projection points, while excluding abnormal data points that do not conform to the model.

In some embodiments, the space outline calculation device 1 can predetermine the number of fitting lines that need to be found (e.g., the number of walls in the estimated space) and the tolerable fitting distance of each data point (e.g., the data points can be considered to be fitted within the range), and the fitting operation is performed based on the above conditions.

Specifically, the processor 13 performs the fitting operation based on a fitting line limit number and a fitting tolerance value to calculate the fitting lines located on the projection plane, wherein a number corresponding to the plurality of fitting lines is not higher than the fitting line limit number and the plurality of projection points constituting each of the plurality of fitting lines meet the fitting

### Tolerance Value.

In some embodiments, since there may be some objects in the space (e.g., a sofa) placed at the boundary of the physical space so that the above calculations generate similar and close fitting lines. In the present example, the processor 13 may select the longer fitting line as the valid fitting line.

In some embodiments, in order to more accurately generate the indoor plane outline, the processor 13 may define the range of the fitting lines and generate the indoor plane outline based on the framed range. Specifically, the processor 13 generates a plurality of fitting line segments corresponding to the plurality of fitting lines based on the plurality of fitting lines and the plurality of projection points constituting each of the plurality of fitting lines. Next, for any two of the plurality of fitting line segments, the processor 13 calculates a plurality of intersection points corresponding to the plurality of fitting line segments. Finally, the processor 13 generates the indoor plane outline based on the plurality of fitting line segments and the plurality of intersection points.

In some embodiments, the processor 13 may set a distance threshold. When two fitting line segments do not intersect but the extended line segments may intersect and fall within the distance threshold, the processor 13 may extend the two fitting line segments to intersect (i.e., tolerance of error distance).

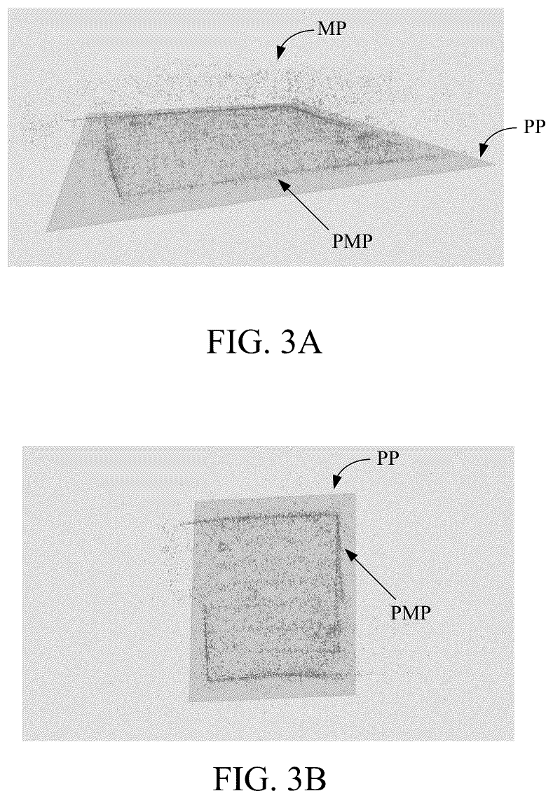

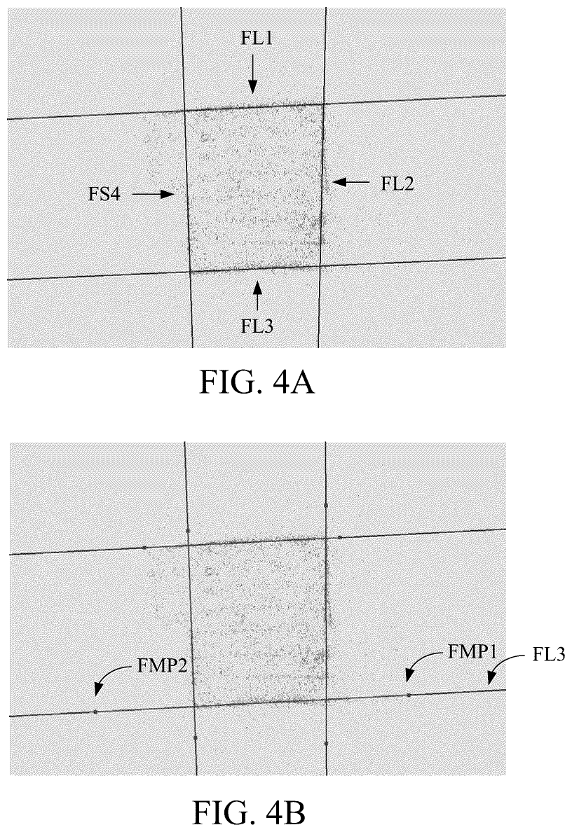

To facilitate understanding of the aforementioned operation, please refer to the schematic diagrams of FIGS. 3A, 3B, 4A, 4B, 5A, and 5B. As shown in FIG. 3A, the processor 13 projects the three-dimensional map point MP onto the projection plane PP, and forms a plurality of projection points PMP on the projection plane PP. In addition, FIG. 4A illustrates a top view of the projection plane PP, the three-dimensional map point MP in space is projected onto the projection plane PP (i.e., the height information of the Z axis is ignored), forming a plurality of projection points PMP.

Next, as shown in FIG. 4A, the processor 13 performs a fitting operation on the plurality of projection points PMP to generate four fitting lines FL1, FL2, FL3, and FL4 that best describe the projection points PMP.

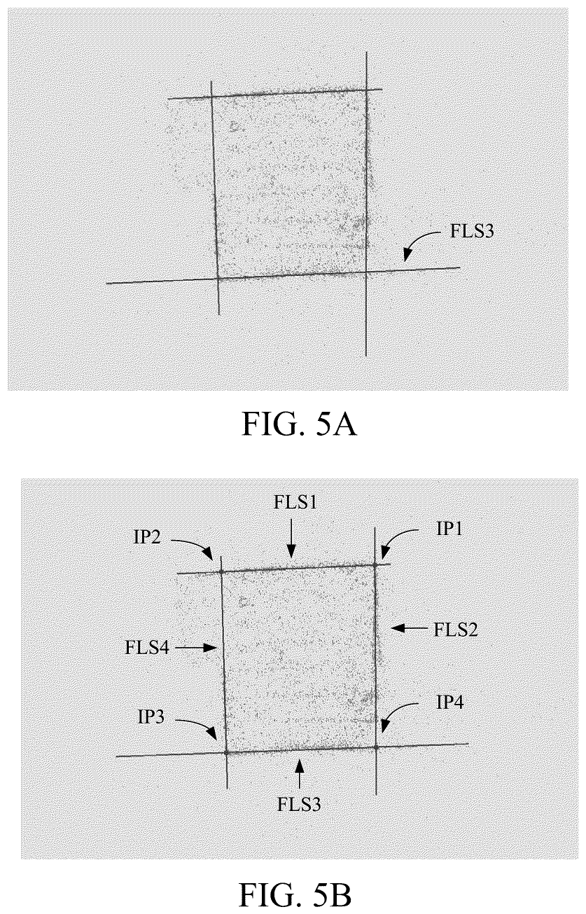

Next, the processor 13 uses the two data points with the farthest distance in each fitting line as the endpoints of each fitting line segment. As shown in FIG. 4B and FIG. 5A, taking the fitting line FL3 as an example, the processor 13 uses the fitting point FMP1 and the fitting point FMP2 on the fitting line FL3 as the end points of the line segment to generate the fitting line segment FLS3.

Next, the processor 13 calculates a plurality of intersection points corresponding to any two of the fitting line segments. As shown in FIG. 5B, the processor 13 calculates the intersection point IP1 of the fitting line segment FLS1 and the fitting line segment FLS2, the intersection point IP2 of the fitting line segment FLS1 and the fitting line segment FLS4, the intersection point IP3 of the fitting line segment FLS4 and the fitting line segment FLS3, and the intersection point IP4 of the fitting line segment FLS3 and the fitting line segment FLS2.

In the present example, the two intersection points can define the range of the fitting line segment to generate the final fitting line segment. For example, the final fitting line segment corresponding to the fitting line segment FLS1 is the range between the intersection point IP1 and the intersection point IP2. Based on the above operation, all the final fitting line segments are generated, and the range framed by the final fitting line segments is the indoor plane outline.

Next, in the present embodiment, the processor 13 generates a plurality of fitting planes with a normal vector (i.e., the second normal vector referred to in some paragraphs of the present disclosure) parallel to a gravity vector based on the plurality of three-dimensional map points.

In some embodiments, in order to make the generated plane data more accurate, the processor 13 may first remove the three-dimensional map points that are outside the area (i.e., the three-dimensional map points whose corresponding projection points are outside the indoor plane outline), and then perform a fitting operation to generate the fitting planes.

Specifically, the processor 13 reduces a weight value of each of the three-dimensional map points located outside the indoor plane outline to update the three-dimensional map points. Next, the processor 13 generates the fitting planes based on the updated three-dimensional map points.

For example, the space outline calculation device 1 may use a random sampling consensus (RANSAC) algorithm to identify the best model (i.e., each fitting plane) among the three-dimensional map points, while excluding outlier data points that do not conform to the model.

In some embodiments, the space outline calculation device 1 can pre-determine the number of fitting planes that need to be found and the tolerable fitting distance of each data point, and perform the fitting operation based on the above conditions.

Next, in the present embodiment, the processor 13 can select two fitting planes from the fitting planes as the upper boundary and the lower boundary of the physical space respectively. Specifically, the processor 13 determines a floor fitting plane and a ceiling fitting plane among the fitting planes.

In some embodiments, when there are too many abnormal map points (e.g., virtual images caused by light reflection), a fitting plane that is lower than the actual floor height may be generated. Therefore, the processor 13 can select a first fitting plane having the same height as the floor height information from the plurality of fitting planes as the floor fitting plane based on the known floor height information (e.g., the floor height is 10 cm in the three-dimensional space coordinates).

In some embodiments, the processor 13 may look in the opposite direction of the floor fitting plane to find the fitting plane with the longest distance as the ceiling fitting plane. Specifically, from the floor fitting plane toward an opposite direction of the gravity vector, the processor 13 selects a second fitting plane from the plurality of fitting planes as the ceiling fitting plane, wherein the second fitting plane has a maximum distance from the floor fitting plane.

Finally, in the present embodiment, the processor 13 combines the indoor plane outline, the floor fitting plane, and the ceiling fitting plane generated by the aforementioned operation to generate a space outline corresponding to the physical indoor space.

In some embodiments, the indoor plane outline is composed of a plurality of final fitting line segments located on the projection plane PP extending upward and downward toward the physical space. Specifically, the processor 13 extends each of the final fitting line segments located on the projection plane PP along a gravity direction and an anti-gravity direction to generate a plurality of vertical planes perpendicular to the floor fitting plane. Next, the processor 13 generates the space outline corresponding to the physical indoor space based on a space area framed by the vertical planes, the floor fitting plane, and the ceiling fitting plane.

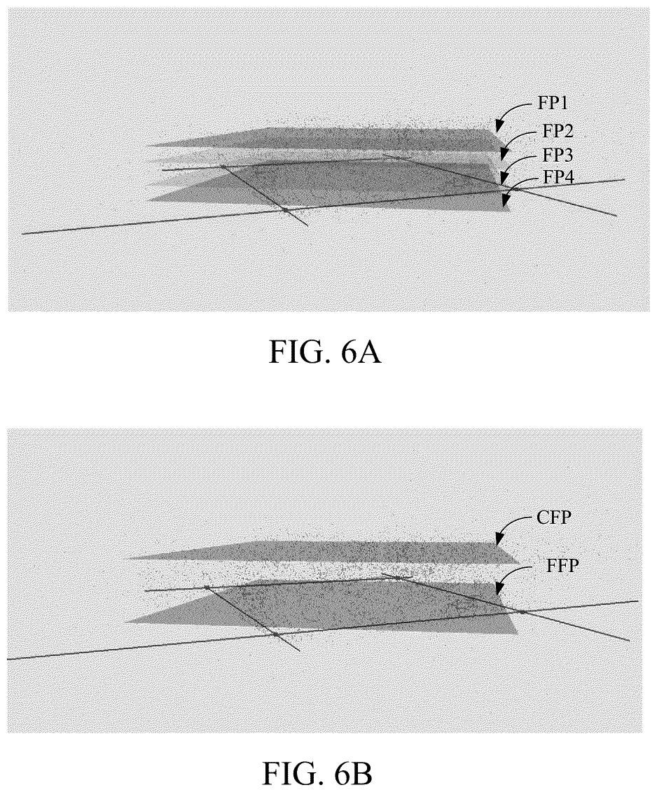

To facilitate understanding of the aforementioned operation, please refer to the schematic diagrams of FIGS. 6A, 6B, 7A, 7B, and 8. As shown in FIG. 6A, the processor 13 generates, based on the three-dimensional map points, a fitting plane FP1, a fitting plane FP2, a fitting plane FP3, and a fitting plane FP4 whose normal vectors are parallel to the gravity vector.

Next, as shown in FIG. 6B, the processor 13 selects the fitting plane FP4 as the floor fitting plane FFP based on the floor height information, and selects the farthest fitting plane FP1 as the ceiling fitting plane CFP along the upward direction of the floor fitting plane FFP.

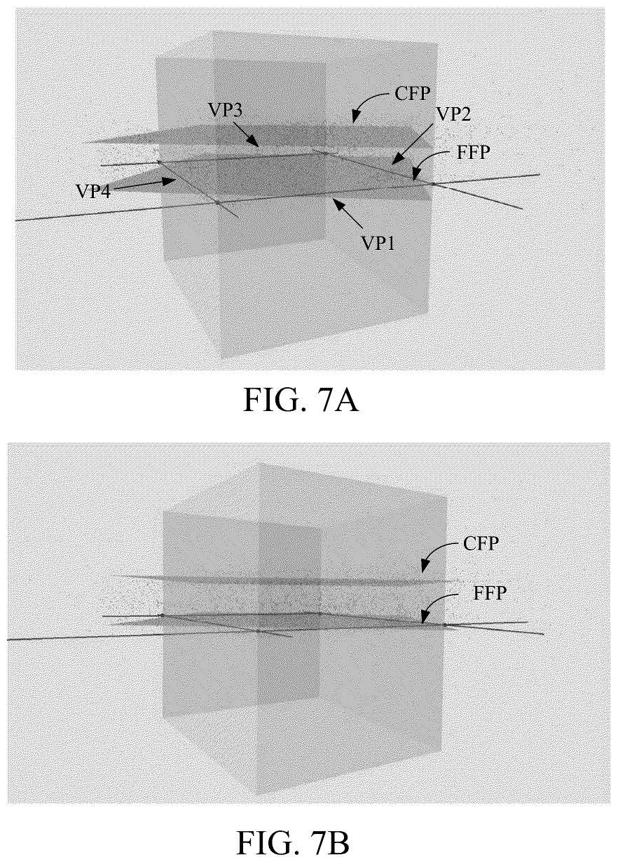

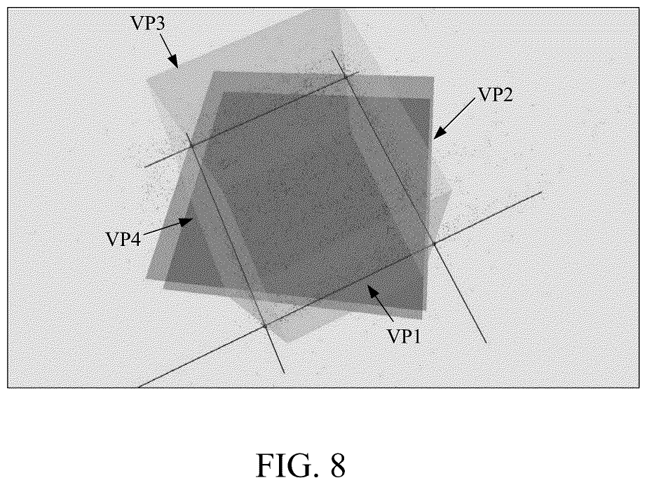

Next, as shown in FIG. 7A, the processor 13 extends each of the final fitting line segments located on the projection plane PP along the gravity direction and the anti-gravity direction, and generates the vertical plane VP1, the vertical plane VP2, the vertical plane VP3, and the vertical plane VP4 which are perpendicular to the floor fitting plane. In the present example, the space area framed by the vertical planes VP1-VP4, the floor fitting plane FFP, and the ceiling fitting plane CFP is the space outline corresponding to the physical indoor space. In addition, FIG. 7B illustrates a schematic diagram of the space outline from another angle, and FIG. 8 illustrates a top view of the space outline.

In some embodiments, the processor 13 may actively remove the three-dimensional map points located outside the spatial outline to update the three-dimensional map points stored in the storage 11.

In some embodiments, the processor 13 can actively reduce the map calculation weights of the three-dimensional map points located outside the spatial outline. Specifically, the processor 13 classifies the three-dimensional map points located within the spatial outline as a regular map point. Next, the processor 13 classifies the three-dimensional map points located outside the spatial outline as an irregular map point, wherein a map operation weight corresponding to the regular map point is higher than the map operation weight corresponding to the irregular map point.

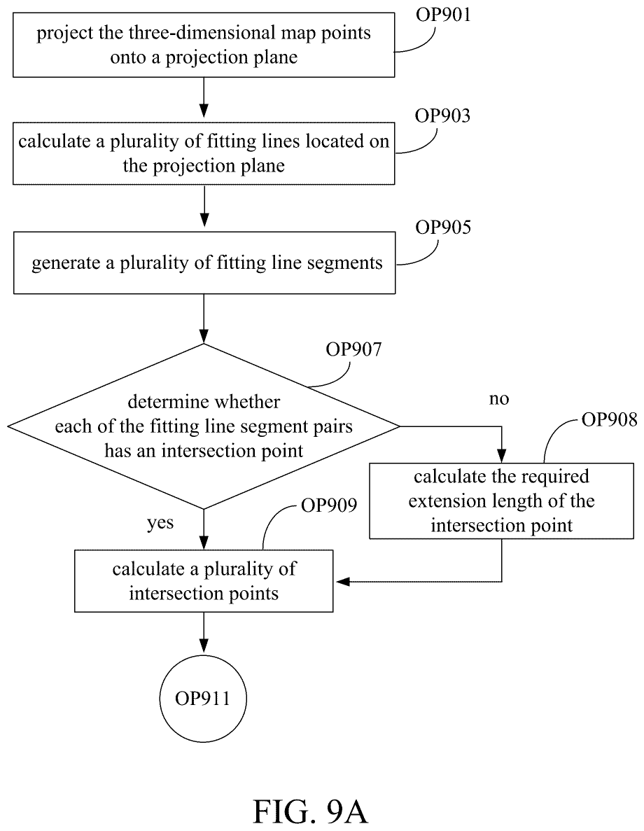

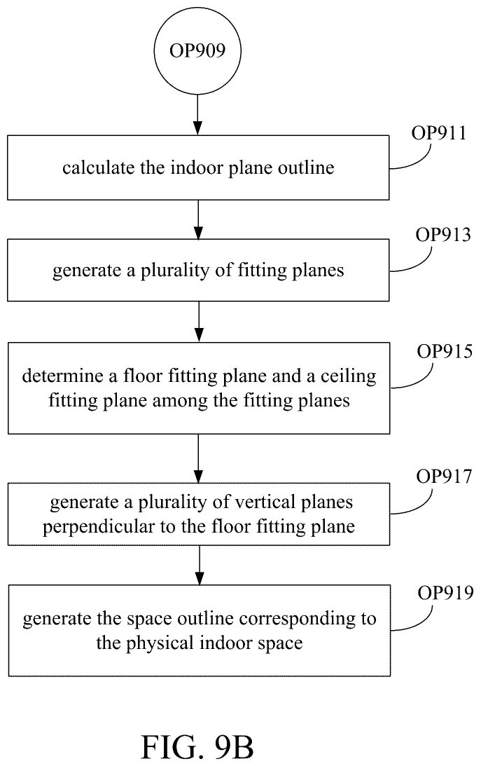

To facilitate understanding of the complete operation of the present disclosure, please refer to the operation schematic diagrams of FIG. 9A and FIG. 9B. First, in the present example, the processor 13 executes the operation OP901 to project the three-dimensional map points onto a projection plane. Next, the processor 13 executes the operations OP903 and OP905 to calculate a plurality of fitting lines located on the projection plane and generate a plurality of fitting line segments corresponding to the fitting lines.

Next, the processor 13 executes the operation OP907 to determine whether each of the fitting line segment pairs (i.e., composed of any two fitting line segments) has an intersection point. If the result is no, the processor 13 executes the operation OP908 to calculate the required extension length of the intersection point. If the processor 13 determines that it is within the tolerance range, the two fitting line segments are extended to intersect.

If the result is yes or the operation OP908 has been completed, the processor 13 executes the operation OP909 to calculate a plurality of intersection points corresponding to the fitting line segments. Next, the processor 13 executes the operation OP911 to calculate the indoor plane outline.

Next, the processor 13 executes the operation OP913 to generate a plurality of fitting planes. Next, the processor 13 executes the operation OP915 to determine a floor fitting plane and a ceiling fitting plane among the fitting planes.

Next, the processor 13 executes the operation OP917 to generate a plurality of vertical planes perpendicular to the floor fitting plane. Finally, the processor 13 executes the operation OP919 to generate the space outline corresponding to the physical indoor space.

According to the above descriptions, the space outline calculation device 1 provided by the present disclosure generates an indoor plane outline through the operation of projecting a plurality of three-dimensional map points and the fitting operation. Next, the space outline calculation device 1 provided by the present disclosure generates a plurality of fitting planes based on the three-dimensional map points, and determines a floor fitting plane and a ceiling fitting plane from the fitting planes. Finally, the space outline calculation device 1 provided by the present disclosure combines the indoor plane outline, the floor fitting plane, and the ceiling fitting plane to generate a space outline corresponding to the physical indoor space. the space outline calculation device 1 provided by the present disclosure can accurately calculate the space outline of the physical indoor space, and correct the three-dimensional map points through the space outline to improve the accuracy of the three-dimensional map points.

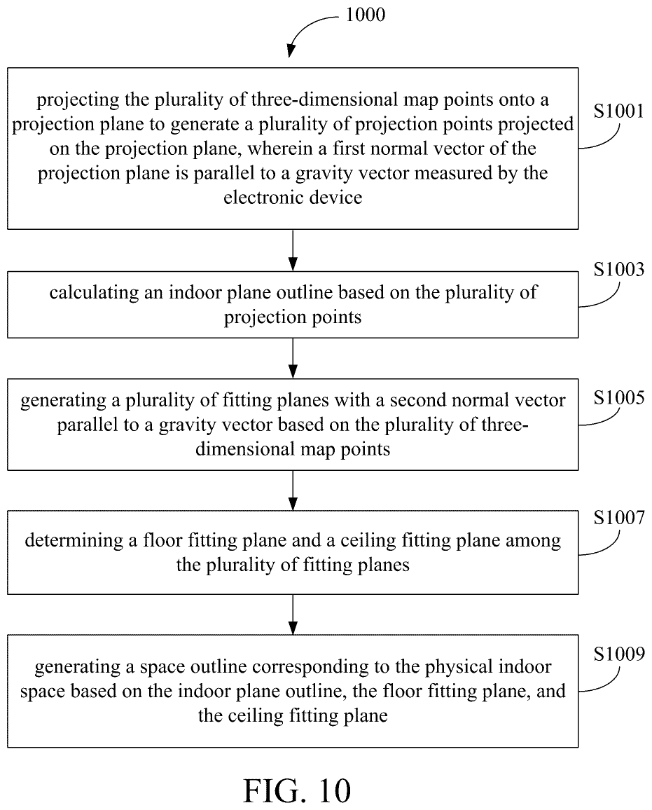

A second embodiment of the present disclosure is a space outline calculation method and a flowchart thereof is depicted in FIG. 10. The space outline calculation method 1000 is adapted for an electronic device (e.g., the space outline calculation device 1 described in the first embodiment). The electronic device is configured to store a plurality of three-dimensional map points corresponding to a physical indoor space. The space outline calculation method 1000 generates a space outline corresponding to the physical indoor space through the steps S1001 to S1009.

In the step S1001, the electronic device projects the plurality of three-dimensional map points onto a projection plane to generate a plurality of projection points projected on the projection plane, wherein a first normal vector of the projection plane is parallel to a gravity vector measured by the electronic device.

Next, in the step S1003, the electronic device calculates an indoor plane outline based on the plurality of projection points. Next, in the step S1005, the electronic device generates a plurality of fitting planes with a second normal vector parallel to a gravity vector based on the plurality of three-dimensional map points.

Next, in the step S1007, the electronic device determines a floor fitting plane and a ceiling fitting plane among the plurality of fitting planes. Finally, in the step S1009, the electronic device generates a space outline corresponding to the physical indoor space based on the indoor plane outline, the floor fitting plane, and the ceiling fitting plane.

In some embodiments, wherein the electronic device further comprises an inertial sensor, and the inertial sensor is configured to sense the gravity vector.

In some embodiments, wherein the step of calculating the indoor plane outline comprises the following steps: performing a fitting operation on the plurality of projection points to calculate a plurality of fitting lines located on the projection plane; and generating the indoor plane outline based on the plurality of fitting lines.

In some embodiments, wherein the space outline calculation method 1000 further comprises the following steps: performing the fitting operation based on a fitting line limit number and a fitting tolerance value to calculate the plurality of fitting lines located on the projection plane, wherein a number corresponding to the plurality of fitting lines is not higher than the fitting line limit number and the plurality of projection points constituting each of the plurality of fitting lines meet the fitting tolerance value.

In some embodiments, wherein the operation of generating the indoor plane outline comprises the following operations: generating a plurality of fitting line segments corresponding to the plurality of fitting lines based on the plurality of fitting lines and the plurality of projection points constituting each of the plurality of fitting lines; for any two of the plurality of fitting line segments, calculating a plurality of intersection points corresponding to the plurality of fitting line segments; and generating the indoor plane outline based on the plurality of fitting line segments and the plurality of intersection points.

In some embodiments, wherein the step of generating the plurality of fitting planes comprises the following steps: reducing a weight value of each of the plurality of three-dimensional map points located outside the indoor plane outline to update the plurality of three-dimensional map points; and generating the plurality of fitting planes based on the updated three-dimensional map points.

In some embodiments, wherein the step of determining the floor fitting plane comprises the following steps: selecting, based on a floor height information, a first fitting plane having the same height as the floor height information from the plurality of fitting planes as the floor fitting plane.

In some embodiments, wherein the step of determining the ceiling fitting plane comprises the following steps: selecting, from the floor fitting plane toward an opposite direction of the gravity vector, a second fitting plane from the plurality of fitting planes as the ceiling fitting plane, wherein the second fitting plane has a maximum distance from the floor fitting plane.

In some embodiments, wherein the indoor plane outline is composed of a plurality of final fitting line segments located on the projection plane, and the step of generating the space outline corresponding to the physical indoor space comprises the following steps: extending each of the plurality of final fitting line segments located on the projection plane along a gravity direction and an anti-gravity direction to generate a plurality of vertical planes perpendicular to the floor fitting plane; and generating the space outline corresponding to the physical indoor space based on a space area framed by the plurality of vertical planes, the floor fitting plane, and the ceiling fitting plane.

In some embodiments, wherein the space outline calculation method 1000 further comprises the following steps: classifying the plurality of three-dimensional map points located within the space outline as a regular map point; and classifying the plurality of three-dimensional map points located outside the space outline as an irregular map point, wherein a map operation weight corresponding to the regular map point is higher than the map operation weight corresponding to the irregular map point.

In addition to the aforesaid steps, the second embodiment can also execute all the operations and steps of the space outline calculation device 1 set forth in the first embodiment, have the same functions, and deliver the same technical effects as the first embodiment. How the second embodiment executes these operations and steps, has the same functions, and delivers the same technical effects will be readily appreciated by those of ordinary skill in the art based on the explanation of the first embodiment. Therefore, the details will not be repeated herein.

The space outline calculation method described in the second embodiment may be implemented by a computer program having a plurality of codes. The computer program may be a file that can be transmitted over the network, or may be stored into a non-transitory computer readable storage medium. After the codes of the computer program are loaded into an electronic device (e.g., the space outline calculation device 1), the computer program executes the space outline calculation method as described in the second embodiment. The non-transitory computer readable storage medium may be an electronic product, e.g., a read only memory (ROM), a flash memory, a floppy disk, a hard disk, a compact disk (CD), a mobile disk, a database accessible to networks, or any other storage medium with the same function and well known to those of ordinary skill in the art.

It shall be appreciated that in the specification and the claims of the present disclosure, some words (e.g., the fitting plane, the normal vector, etc.) are preceded by terms such as “first” or “second”, and these terms of “first” or “second” are only used to distinguish these different words. For example, the “first” and “second” fitting planes are only used to indicate the fitting plane used in different operations.

According to the above descriptions, the space outline calculation technology (at least including the device and the method) provided by the present disclosure generates an indoor plane outline through the operation of projecting a plurality of three-dimensional map points and the fitting operation. Next, the space outline calculation technology provided by the present disclosure generates a plurality of fitting planes based on the three-dimensional map points, and determines a floor fitting plane and a ceiling fitting plane from the fitting planes. Finally, the space outline calculation technology provided by the present disclosure combines the indoor plane outline, the floor fitting plane, and the ceiling fitting plane to generate a space outline corresponding to the physical indoor space. The space outline calculation technology provided by the present disclosure can accurately calculate the space outline of the physical indoor space, and correct the three-dimensional map points through the space outline to improve the accuracy of the three-dimensional map points.

The above disclosure is related to the detailed technical contents and inventive features thereof. People skilled in this field may proceed with a variety of modifications and replacements based on the disclosures and suggestions of the disclosure as described without departing from the characteristics thereof. Nevertheless, although such modifications and replacements are not fully disclosed in the above descriptions, they have substantially been covered in the following claims as appended.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A space outline calculation device, comprising:
a storage, being configured to store a plurality of three-dimensional map points corresponding to a physical indoor space; and
a processor, being electrically connected to the storage, and being configured to perform the following operations:
projecting the plurality of three-dimensional map points onto a projection plane to generate a plurality of projection points projected on the projection plane, wherein a first normal vector of the projection plane is parallel to a gravity vector measured by the space outline calculation device;
calculating an indoor plane outline based on the plurality of projection points;
generating a plurality of fitting planes with a second normal vector parallel to a gravity vector based on the plurality of three-dimensional map points;
determining a floor fitting plane and a ceiling fitting plane among the plurality of fitting planes; and
generating a space outline corresponding to the physical indoor space based on the indoor plane outline, the floor fitting plane, and the ceiling fitting plane.

2. The space outline calculation device of claim 1, wherein the space outline calculation device further comprises:
an inertial sensor, being electrically connected to the processor, wherein the inertial sensor is configured to sense the gravity vector.

3. The space outline calculation device of claim 1, wherein the operation of calculating the indoor plane outline comprises the following operations:
performing a fitting operation on the plurality of projection points to calculate a plurality of fitting lines located on the projection plane; and
generating the indoor plane outline based on the plurality of fitting lines.

4. The space outline calculation device of claim 3, wherein the processor further performs the following operations:
performing the fitting operation based on a fitting line limit number and a fitting tolerance value to calculate the plurality of fitting lines located on the projection plane, wherein a number corresponding to the plurality of fitting lines is not higher than the fitting line limit number and the plurality of projection points constituting each of the plurality of fitting lines meet the fitting tolerance value.

5. The space outline calculation device of claim 3, wherein the operation of generating the indoor plane outline comprises the following operations:
generating a plurality of fitting line segments corresponding to the plurality of fitting lines based on the plurality of fitting lines and the plurality of projection points constituting each of the plurality of fitting lines;
for any two of the plurality of fitting line segments, calculating a plurality of intersection points corresponding to the plurality of fitting line segments; and
generating the indoor plane outline based on the plurality of fitting line segments and the plurality of intersection points.

6. The space outline calculation device of claim 1, wherein the operation of generating the plurality of fitting planes comprises the following operations:
reducing a weight value of each of the plurality of three-dimensional map points located outside the indoor plane outline to update the plurality of three-dimensional map points; and
generating the plurality of fitting planes based on the updated three-dimensional map points.

7. The space outline calculation device of claim 1, wherein the operation of determining the floor fitting plane comprises the following operations:
selecting, based on a floor height information, a first fitting plane having the same height as the floor height information from the plurality of fitting planes as the floor fitting plane.

8. The space outline calculation device of claim 1, wherein the operation of determining the ceiling fitting plane comprises the following operations:
selecting, from the floor fitting plane toward an opposite direction of the gravity vector, a second fitting plane from the plurality of fitting planes as the ceiling fitting plane, wherein the second fitting plane has a maximum distance from the floor fitting plane.

9. The space outline calculation device of claim 1, wherein the indoor plane outline is composed of a plurality of final fitting line segments located on the projection plane, and the operation of generating the space outline corresponding to the physical indoor space comprises the following operations:
extending each of the plurality of final fitting line segments located on the projection plane along a gravity direction and an anti-gravity direction to generate a plurality of vertical planes perpendicular to the floor fitting plane; and
generating the space outline corresponding to the physical indoor space based on a space area framed by the plurality of vertical planes, the floor fitting plane, and the ceiling fitting plane.

10. The space outline calculation device of claim 1, wherein the processor further performs the following operations:
classifying the plurality of three-dimensional map points located within the space outline as a regular map point; and
classifying the plurality of three-dimensional map points located outside the space outline as an irregular map point, wherein a map operation weight corresponding to the regular map point is higher than the map operation weight corresponding to the irregular map point.

11. A space outline calculation method, being adapted for use in an electronic device, wherein the electronic device is configured to store a plurality of three-dimensional map points corresponding to a physical indoor space, and the space outline calculation method comprises:
projecting the plurality of three-dimensional map points onto a projection plane to generate a plurality of projection points projected on the projection plane, wherein a first normal vector of the projection plane is parallel to a gravity vector measured by the electronic device;
calculating an indoor plane outline based on the plurality of projection points;
generating a plurality of fitting planes with a second normal vector parallel to a gravity vector based on the plurality of three-dimensional map points;
determining a floor fitting plane and a ceiling fitting plane among the plurality of fitting planes; and
generating a space outline corresponding to the physical indoor space based on the indoor plane outline, the floor fitting plane, and the ceiling fitting plane.

12. The space outline calculation method of claim 11, wherein the electronic device further comprises an inertial sensor, and the inertial sensor is configured to sense the gravity vector.

13. The space outline calculation method of claim 11, wherein the step of calculating the indoor plane outline comprises the following steps:
performing a fitting operation on the plurality of projection points to calculate a plurality of fitting lines located on the projection plane; and
generating the indoor plane outline based on the plurality of fitting lines.

14. The space outline calculation method of claim 13, wherein the space outline calculation method further comprises the following steps:
performing the fitting operation based on a fitting line limit number and a fitting tolerance value to calculate the plurality of fitting lines located on the projection plane, wherein a number corresponding to the plurality of fitting lines is not higher than the fitting line limit number and the plurality of projection points constituting each of the plurality of fitting lines meet the fitting tolerance value.

15. The space outline calculation method of claim 13, wherein the operation of generating the indoor plane outline comprises the following operations:
generating a plurality of fitting line segments corresponding to the plurality of fitting lines based on the plurality of fitting lines and the plurality of projection points constituting each of the plurality of fitting lines;
for any two of the plurality of fitting line segments, calculating a plurality of intersection points corresponding to the plurality of fitting line segments; and
generating the indoor plane outline based on the plurality of fitting line segments and the plurality of intersection points.

16. The space outline calculation method of claim 11, wherein the step of generating the plurality of fitting planes comprises the following steps:
reducing a weight value of each of the plurality of three-dimensional map points located outside the indoor plane outline to update the plurality of three-dimensional map points; and
generating the plurality of fitting planes based on the updated three-dimensional map points.

17. The space outline calculation method of claim 11, wherein the step of determining the floor fitting plane comprises the following steps:
selecting, based on a floor height information, a first fitting plane having the same height as the floor height information from the plurality of fitting planes as the floor fitting plane.

18. The space outline calculation method of claim 11, wherein the step of determining the ceiling fitting plane comprises the following steps:
selecting, from the floor fitting plane toward an opposite direction of the gravity vector, a second fitting plane from the plurality of fitting planes as the ceiling fitting plane, wherein the second fitting plane has a maximum distance from the floor fitting plane.

19. The space outline calculation method of claim 11, wherein the indoor plane outline is composed of a plurality of final fitting line segments located on the projection plane, and the step of generating the space outline corresponding to the physical indoor space comprises the following steps:
extending each of the plurality of final fitting line segments located on the projection plane along a gravity direction and an anti-gravity direction to generate a plurality of vertical planes perpendicular to the floor fitting plane; and
generating the space outline corresponding to the physical indoor space based on a space area framed by the plurality of vertical planes, the floor fitting plane, and the ceiling fitting plane.

20. The space outline calculation method of claim 11, wherein the space outline calculation method further comprises the following steps:
classifying the plurality of three-dimensional map points located within the space outline as a regular map point; and
classifying the plurality of three-dimensional map points located outside the space outline as an irregular map point, wherein a map operation weight corresponding to the regular map point is higher than the map operation weight corresponding to the irregular map point.
